(19) United States
(12) Patent Application Publication
(10) Pub. No.: US 2020/0292593 A1
(43) Pub. Date: Sep. 17, 2020

(54) APPARATUS AND METHOD FOR AN IMPROVED VOLTAGE DETECTOR

(71) Applicant: Myron Jones, Rosedale, MD (US)

(72) Inventor: Myron Jones, Rosedale, MD (US)

(21) Appl. No.: 16/352,807

(22) Filed: Mar. 13, 2019

(51) Int. Cl. G01R 19/155; G01R 1/067; H02H 3/04

(52) U.S. Cl. CPC G01R 19/155; H02H 3/04; G01R 1/06777

(57) ABSTRACT

A voltage detector is presented. The voltage detector is a rod that has a handle at the proximal end. The distal end of the rod has a voltage probe. The voltage detector has an energy source and an indicator.

### FIELD OF THE INVENTION

The present invention relates generally to voltage detectors, and more particularly to an extendable voltage detector.

### BACKGROUND

Electrical power distribution systems often include overhead electrical power distribution lines mounted upon poles by a wide variety of mounting structure. Other distribution systems include underground distribution lines in which protected cables run under the ground surface. It is often necessary to take voltage measurements of distribution and transmission lines while testing for induced or live power line or equipment.

Known high voltage safety line detectors, meters and testers comprise high resistance probes connected in series with a calibrated panel meter to read the voltage. They are designed for use as safety tools by high voltage line maintenance workers to verify the status of the line or equipment as nominal, induced or de-energized. Known devices for providing such measurements include contact type and non-contact type.

The direct high voltage measurement by contacting the live high voltage power lines by using high voltage measuring and detecting equipment is often cumbersome due to distance of the power line from the ground. There are also safety concerns since voltage levels are generally more than 69 kV in an electrical power system.

A non-contact type measurement technique does not require that the testing equipment directly contact the power line. However, the conventional non-contact voltage testing devices determine only the presence of a voltage on the line. They do not show the magnitude of the voltage.

The approximate magnitude of the voltage is necessary to understand the voltage levels in the electrical power system. Also, decisions must often be made with respect to voltage presence due to induced voltage or voltage due to overloading or voltage levels of different electrical lines. There can also be voltage accuracy issues with floating high voltages.

### BRIEF DESCRIPTION OF THE DRAWINGS

FIG. 1 is a view an exemplary voltage detector.

FIG. 2 is a flowchat of the method for detecting a voltage.

### DETAILED DESCRIPTION

Reference will now be made in detail to the present preferred embodiments, examples of which are illustrated in the accompanying drawings. All terms in the plural shall also be taken as singular and vice-versa. Further, any reference to he shall also be applicable to she and vice-versa.

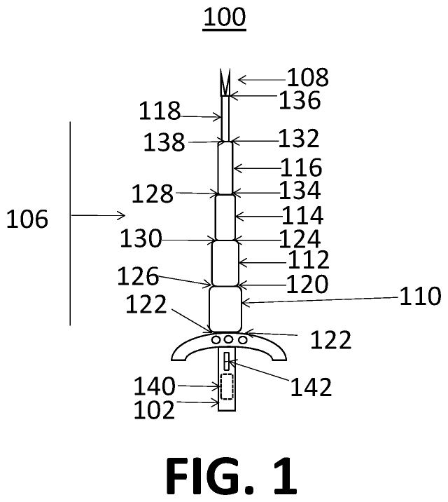

Referring now to FIG. 1, an exemplary voltage detector 100 is presented. The voltage detector 100 is useful in determining if a voltage on a given source exceeds a threshold that would put one in peril. The voltage detector 100 has a handle 102, a display panel 104, a rod 106 and a voltage probe 108. The handle 102 may be rubber, cork, carbon fiber, etc.

The display panel 104 of the voltage detector 100 is useful to display the caution status of an electrical charge. The display panel 104 can be lamps, a LED display, a speaker, any combination of the aforementioned, etc.

The rod 106 can be a solid or hollow material. The rod 106 may be in one complete piece or may be extendable to reach further distances without be clumsy to use. The rod may have a first portion 110, a second portion 112, a third portion 114, a fourth portion 116 and a fifth portion 118. Each of the portions may be any length and size. The exemplary portions each slide into the portion before and after that portion. To secure the connection of each of the portions a secure connection mechanism may be employed, such mechanisms may be an inter-connected portion, a hole and button connector, a strap connector, a coupler, etc.

The first portion 110 has a distal end 120 and a proximal end 122. The proximal end 122 of the first portion is coupled to the handle 102 to form the base of the rod 106. The display panel 104 may be placed between or at the coupling of the handle 102 and the proximal end of the first portion 110.

The second portion 112 has a distal end 124 and a proximal end 126. The proximal end 124 of the second portion 112 is coupled to the distal end 120 of the first portion 110 to form a first extendable portion of the rod 106. The coupling may be an inter-connected portion, a hole and button connector, a strap connector, a coupler, etc.

The third portion 114 has a distal end 128 and a proximal end 130. The proximal end 130 of the third portion 114 is coupled to the distal end 124 of the second portion 112 to form a second extendable portion of the rod 106. The coupling may be an inter-connected portion, a hole and button connector, a strap connector, a coupler, etc.

The fourth portion 116 has a distal end 132 and a proximal end 134. The proximal end 134 of the fourth portion 116 is coupled to the distal end 128 of the third portion 114 to form a third extendable portion of the rod 106. The coupling may be an inter-connected portion, a hole and button connector, a strap connector, a coupler, etc.

The fifth portion 118 has a distal end 136 and a proximal end 138. The proximal end 138 of the fifth portion 118 is coupled to the distal end 132 of the fourth portion 116 to form a fourth extendable portion of the rod 106. The coupling may be an inter-connected portion, a hole and button connector, a strap connector, a coupler, etc.

The voltage probe 108 is useful to couple with an electrical circuit or to be able to detect an electric charge in a source to be detected. The voltage probe 108 determines a value of the charge and sends the value of the charge to the display panel 104.

The display panel 104 has a processor which determines if the value of the charge exceeds a pre-determined threshold. If the value of the charge exceeds the pre-determined threshold, then a warning indicator is activated and if a speaker is attached to display panel 104, then a verbal alert is sounded.

If the display panel 104 determines that the value of the charge has not exceeded the predetermined threshold, then an indicator may be activated to indicate that the electrical source is safe.

The handle 102 also has an energy source 140, the energy source 140 may be a replaceable battery, a Nicad battery, a rechargeable battery, etc. The energy source 140 is coupled to an actuator 142. The actuator 142 may be a push button, a switch, an icon on the display panel, a toggle switch, etc. The actuator 142 is useful in turning the voltage detector 100 on.

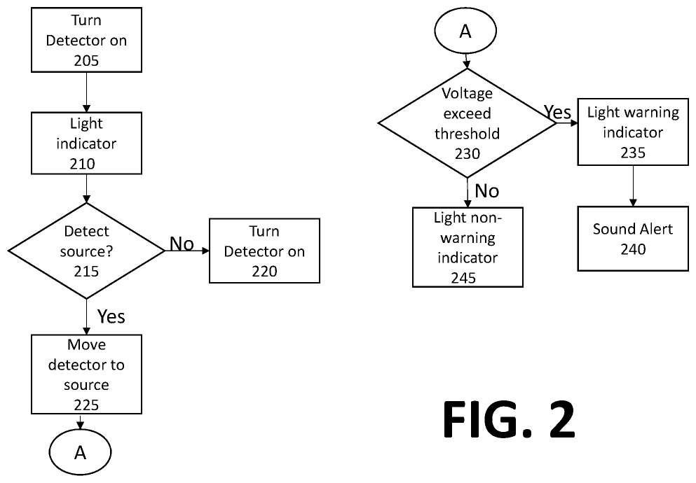

Moving now to FIG. 2, a flowchart of the voltage detector is described. At 200, the voltage detector 100 is actuated by pressing or actuating the actuator 142. The actuator 142 may be a push button, a switch, an icon on the display panel, a toggle switch, etc

Once the voltage detector 100 has been turned on, at 210, an indicator is activated at the display panel 104 to indicate that the voltage detector 100 has been turned on. The indicator may be a lamp, an LED display, etc.

At 220 a determination is made if a source has been detected, if a source has not been detected, then the voltage detector 100 may be set to power down automatically or may continue to stay on.

If a source was detected at 220, then at 225 the voltage detector 100 is moved towards the detected source. The voltage detector 100 receives the charge from the detected source and determines a value of the voltage at the source.

At 230, the value of the charge from detected source is compared against a predetermined threshold. If the threshold has been exceeded, then the display panel 104 displays a warning indicator, notifying the user that the voltage detected can be hazardous. If a speaker has been coupled to the voltage detector 100, then an alert is sounded at 240.

If at 230, the value of the charge of the detected source has not exceeded the pre-determined threshold, then at 245 an indication is made to the user that the detected source's electrical charge is not hazardous.

The features described with respect to one embodiment may be applied to other embodiments or combined with or interchanged with the features of other embodiments, as appropriate, without departing from the scope of the present invention.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A voltage detector, the voltage detector comprising:
a rod;
the rod having a proximal end, a distal end, an exterior surface and an interior surface;
a handle coupled to the proximal end of the rod;
a voltage probe coupled to the distal end of the rod; and
an energy source coupled to the interior surface of the rod; and
a voltage indicator coupled to voltage probe coupled to the exterior of the surface and the energy source.

2. The voltage detector of claim 1, wherein the rod is metal.

3. The voltage detector of claim 1, wherein the energy source is a battery.

4. The voltage detector of claim 1, wherein the handle is rubber.

5. The voltage detector of claim 1, wherein the rod is telescopic.

6. The voltage detector of claim 1, wherein the rod further comprises a first portion and a second portion, wherein the first portion engages with the second portion to extend the length of the rod.

7. The voltage detector of claim 1, wherein the voltage indicator is a light.

8. The voltage detector of claim 7, wherein the light is LED.

9. The voltage detector of claim 1, wherein the voltage indicator is a gauge.

10. The voltage detector of claim 1, wherein the voltage detector is a display screen.

11. The voltage detector of claim 1, further comprising a power switch, the power switch being coupled to the energy source and the handle.

12. The voltage detector of claim 11, wherein the power switch is wireless.

13. The voltage detector of claim 11, wherein the power switch is a toggle switch.

14. The voltage detector of claim 1, wherein the energy source is Nicad.

15. A method to detect voltage, the method comprising:
Activating a voltage detector;
Lighting an indicator lamp, wherein the indicator lamp indicates the voltage detector is powered on;
Determine if a source has been detected;
when the source has been detected, determine if the voltage exceeds a threshold; and
when the voltage exceeds the threshold, light a warning indicator lamp.

16. The method of claim 15, further comprising when the voltage exceeds the threshold, sounding an audible alarm.

17. The method of claim 15, further comprising when a voltage threshold has not been exceeded light a non-warning indicator lamp.

18. The method of claim 15, wherein the warning indicator lamp and non-warning indicator lamp are a display panel.

19. The method of claim 15, wherein the voltage detector is metal.

20. The method of claim 15, wherein the activating the voltage detector is an on/off switch.
